(19) United States
(12) Patent Application Publication
(10) Pub. No.: US 2024/0201113 A1
(43) Pub. Date: Jun. 20, 2024

(54) PARTICLE ANALYZING DEVICE, AND PARTICLE ANALYZING METHOD

(71) Applicant: HITACHI HIGH-TECH CORPORATION, Tokyo (JP)

(72) Inventors: Akiko HISADA, Tokyo (JP); Yuusuke OOMINAMI, Tokyo (JP); Erino MATSUMOTO, Tokyo (JP)

(21) Appl. No.: 18/288,042

(22) PCT Filed: May 26, 2021
(86) PCT No.: PCT/JP2021/020018

§ 371 Date: Oct. 24, 2023

(51) Int. Cl. G01N 23/2251

(52) U.S. Cl. CPC G01N 23/2251; G01N 2223/401

(57) ABSTRACT

In a particle analyzing device for analyzing a predetermined particle to be analyzed, placed on an instrument, with an electron microscope, the particle analyzing device acquires a first standard value and a second standard value regarding brightness in an electron microscope image, the particle analyzing device acquires an electron microscope image and a signal profile generated by irradiating the instrument and the particle with an electron beam, and the particle analyzing device adjusts brightness of the electron microscope image based on the first standard value, the second standard value, and the signal profile.

### TECHNICAL FIELD

The present invention relates to a particle analyzing device and a particle analyzing method.

### BACKGROUND ART

Analysis and evaluation of particles of about 100 nanometers to several hundred micrometers are very important from the material field to the bio field and the environmental field. In the material field, the number of industries that utilize particles is increasing due to recent development of nano-microtechnology. Examples of the particles include dielectric particles used for a capacitor in association with miniaturization of an electronic circuit, and conductive fine particles used for an electrode material in association with increase in capacity of a battery. From the viewpoint of manufacturing, it is important to evaluate the properties of these particles and to analyze foreign particles mixed in a material manufacturing process. Furthermore, in the biomedical field, for example, particles such as cancer cells, blood cells, bacteria, viruses, and aggregates are analyzed by clinical examination or the like. On the other hand, in the environmental field, as a negative aspect of industrial development, particles that cause environmental and health problems, such as asbestos, microplastics, and microparticulate matter (PM 2.5), are analyzed. As described above, the analysis of particles is important not only for industrial use of the particles themselves but also as an evaluation index of a manufacturing process, a disease, an environment, and the like.

In order to analyze fine particles, not limited to the particles exemplified, in detail, an electron microscope can be used. Since the electron microscope has a resolution of a nanometer size, it has performance necessary for the analysis of the above-described particles. PTL 1 discloses a method of analyzing particles by irradiating the particles with an electron beam while keeping each of fine particles collected.

In general, in analysis using an electron microscope, since a specimen is placed in a sample chamber in a vacuum environment and is irradiated with an electron beam, it is difficult to analyze particles dispersed in air or in a solution as they are. Therefore, in order to analyze particles dispersed in air or in a solution with an electron microscope, a method is often used in which particles to be analyzed are collected on an instrument that can be introduced into an electron microscope sample chamber, a dried specimen is prepared, and the particles on the instrument are irradiated with an electron beam.

PTL 2 discloses a method in which atmospheric fine particles having a specific particle diameter or less classified by a classifier are collected on a track etched membrane filter, and the fine particles on the track etched membrane filter are irradiated with an electron beam or the like to analyze the fine particles.

Furthermore, PTL 3 discloses a method of separating particles contained in a paste, preparing a specimen as a dry coating film, observing the specimen with a scanning electron microscope, and evaluating the particles by image analysis.

### CITATIONS LIST

### Patent Literatures

PTL 1: JP 2011-163872 A
PTL 2: JP 2017-72593 A
PTL 3: JP 2015-161536 A

### SUMMARY OF INVENTION

### Technical Problem

However, the conventional technique has a problem that it is difficult to adjust the brightness of the electron microscope image.

When particles are analyzed with an electron microscope, it is common to prepare a specimen in which the particles are placed on an instrument as in PTL 2 described above. Moreover, in a case where particles placed under a certain condition are compared with control particles for inspection, the particles are often sampled for each condition to prepare each specimen, and each specimen is analyzed with an electron microscope to compare each image. That is, rather than comparing particles placed under different conditions in the same image, a plurality of different images is often compared.

For example, in the case of comparing and inspecting fine particles generated in different manufacturing processes, a part of the fine particles generated for each manufacturing process is sampled to prepare a specimen mounted on an instrument, and an electron microscope image of each specimen is acquired. Alternatively, in the case of inspecting the degree of abnormality in size and shape of a biologically derived particle such as a cell, a specimen in which normal cells and abnormal cells are placed on an instrument is prepared, and an electron microscope image of each specimen is acquired. Furthermore, in the case of inspecting a temporal change of a cell or the like, a part of the cell population placed under a certain condition is sampled over time to prepare specimens each of which is placed on an instrument, and an electron microscope image of each specimen is acquired. Furthermore, in the case of monitoring a change in the concentration of fine particles in the environment or the like, sampling is performed over time to prepare specimens each of which is placed on an instrument, and an electron microscope image of each specimen is acquired.

In the inspection or monitoring described as an example, analysis is often performed using a certain type of specimen instrument or analysis device in accordance with a particle to be analyzed or an analysis purpose. Then, a plurality of images such as a control specimen or a plurality of particle specimens sampled under different conditions are often compared with a certain reference.

Here, as an electron microscope image acquisition condition for comparing a plurality of images with a certain reference, it is desirable that image adjustment conditions such as brightness and contrast are met between separately acquired images.

The reason for this is the ease of image analysis. For example, as a method of extracting an image region of a particle in a case where regions of an instrument and a particle are mixed in an electron microscope image, a method of extracting a particle region by binarizing an image with a threshold that can divide the instrument region as a background and the particle region is known.

Here, when a certain particle is analyzed, if the particle is placed on the same type of instrument and the brightness and contrast adjustment of the image are made constant, the image can be binarized with the same threshold in principle even in the case of separately acquired images.

Alternatively, even in a case where an image is analyzed using artificial intelligence, if the acquisition conditions of the learning image and the evaluation image are constant, a more accurate image analysis result can be obtained.

However, it is not easy to acquire different images with the same brightness and contrast adjustment due to a case where a plurality of inspection devices is used in parallel to analyze a plurality of specimens, a change in a state of an electron gun that emits an electron beam, or other factors. As one of methods of coping with this problem, a method of adjusting image adjustment conditions using a standard sample prepared in advance is adopted. However, in this case, adjustment may need to be repeated by putting the standard sample prepared separately from the particle to be analyzed in and out of the electron microscope sample chamber or changing the field of view.

The present invention has been made in view of such a situation, and an object thereof is to provide a particle analyzing device and a particle analyzing method that make it easier to adjust the brightness of an electron microscope image.

### Solution to Problem

An example of a particle analyzing device according to the present invention is a particle analyzing device for analyzing a predetermined particle to be analyzed, placed on an instrument, with an electron microscope, in which
the particle analyzing device acquires a first standard value and a second standard value regarding brightness in an electron microscope image,
the particle analyzing device acquires an electron microscope image and a signal profile generated by irradiating the instrument and the particle with an electron beam, and
the particle analyzing device adjusts brightness of the electron microscope image based on the first standard value, the second standard value, and the signal profile.

An example of a particle analyzing method according to the present invention is a particle analyzing method for analyzing a predetermined particle to be analyzed, placed on an instrument, with an electron microscope, the particle analyzing method including:
acquiring a first standard value and a second standard value regarding brightness in an electron microscope image;
acquiring an electron microscope image and a signal profile generated by irradiating the instrument and the particle with an electron beam; and
adjusting brightness of the electron microscope image based on the first standard value, the second standard value, and the signal profile.

### Advantageous Effects of Invention

According to the technique according to the present invention, it is easier to adjust the brightness of the electron microscope image.

### BRIEF DESCRIPTION OF DRAWINGS

FIG. 1 is a schematic diagram of a configuration of a specimen and an example of a specimen image according to Example 1 of the present invention.

FIG. 2 is a schematic configuration diagram of a particle analyzing device according to Example 1.

FIG. 3 is a schematic diagram of an example of image brightness and contrast adjustment according to Example 1.

FIG. 4 is a schematic diagram of an example of an instrument according to Example 2.

FIG. 5 is a flowchart of particle analysis according to Example 3.

FIG. 6 illustrates an example in which blood cells are analyzed according to Example 4.

FIG. 7 illustrates an example in which a cell proliferation rate was analyzed according to Example 5.

### DESCRIPTION OF EMBODIMENTS

Hereinafter, examples of the present invention will be described.

### Example 1

In Example 1, when particles are analyzed with an electron microscope, a specimen in which the particles are placed on an instrument is prepared.

The particles include, but are not limited to, the following:
Particles formed by grinding, sintering, or crystallization;
A three-dimensional structure such as a step or a pattern deposited or formed on a surface by corrosion, by plating, or by a chemical reaction of a battery or the like;
Void or flaw generated by material degradation or etching;
Foreign matter generated as external factor; and
A fiber that is an organic substance, a microplastic, a pollen, a blood cell, a cell, a bacterium, a virus, a protein aggregate, or a complex thereof.

In the present example, plastic or a cellulose-based membrane is taken as an example of an instrument, but the instrument is not limited thereto. The instrument of the present example includes a surface from which an electron microscope image of a particle to be analyzed can be obtained, and may be, for example, a metal plate, a glass plate, a silicon substrate, a metal mesh, or the like, or may be a surface having a three-dimensional structure sufficiently smaller than the particle to be analyzed.

In the description of the present example, a difference in image brightness due to a three-dimensional structure, such as a hole penetrating a membrane or an overlap of fibers, is taken as an example of a region in the instrument having a different brightness of an image from a background of the instrument, but the present invention is not limited thereto. For example, a region formed by combining different materials, a printed region, or a composite region thereof is also included.

### Configuration Example of Particle Analyzing Device

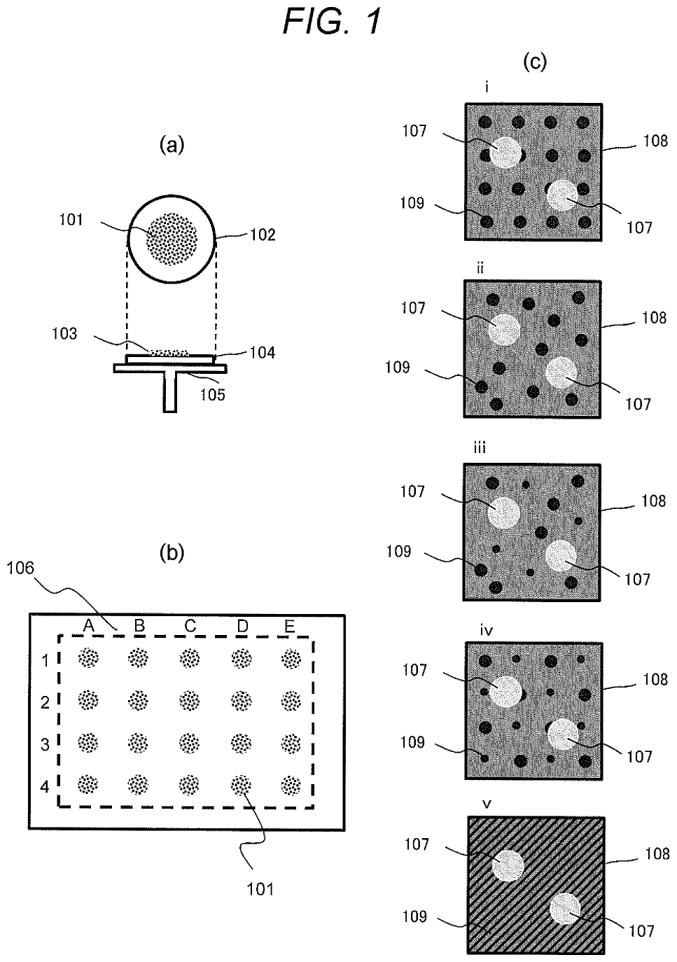

An example of a configuration of a particle specimen and a specimen image analyzed by the device of the present example will be described with reference to FIG. 1. In FIG. 1 (a), 101 denotes particles to be analyzed in a specimen, 102 denotes a top view of an instrument, 103 denotes a side view of the particles to be analyzed, 104 denotes a side view of the instrument, and 105 denotes a scanning electron microscope (SEM) sample stage. Note that, in FIG. 1 and the subsequent drawings, the same constituent elements appearing in different views may be denoted by different reference signs.

In FIG. 1 (b), 106 denotes a top view of an instrument for a plurality of specimens different from that in FIG. 1 (a).

In FIG. 1 (c), 107 denotes a schematic view of an SEM image of particles to be analyzed in a specimen, 108 denotes a schematic view of an SEM image of a background region of an instrument, and 109 denotes a schematic view of an SEM image of a region having different brightness in an instrument. This figure does not necessarily correspond to the instrument of FIG. 1 (a) or 1 (b).

The particles to be analyzed 101 or 103 are placed on an upper surface of the instrument 102, 104 or 106, and the instrument is placed on the sample stage 105 of the SEM. There may be one or a plurality of regions where the particles are placed on one instrument. In the example of FIG. 1 (a), there is one place, and in the example of FIG. 1 (b), there are a plurality of places (five columns and four rows).

As an example of a specimen image when the region on which the particles 101 are placed is observed with the SEM, FIG. 1 (c) illustrates an image in which the particles 107, an instrument background 108 having image brightness darker than that of the particles 107, and regions 109 darker than that of the background exist. The darker-than-background regions are exemplified by, but not limited to, schematic diagrams of (i) a plurality of aligned particulate patterns of the same size, (ii) a plurality of non-aligned particulate patterns of the same size, (iii) non-aligned particulate patterns of different sizes, (iv) aligned particulate patterns of different sizes, and (v) a fibrous pattern.

Furthermore, the example in which the background of the instrument and the region inside the instrument and having different brightness are darker than the particles to be analyzed has been described. However, as long as the brightness is different from that of the particles to be analyzed, both or any of the regions may be brighter than the particles to be analyzed.

As described above, the particle analyzing device according to the present example is a device for analyzing a predetermined particle to be analyzed, placed on an instrument, with an electron microscope. The instrument includes a first region (for example, background 108) having different brightness from the particle and a second region (for example, region 109 darker than the background) having different brightness from the particle and the first region when observed with an electron microscope.

A material constituting the first region and a material constituting the second region may be different. Additionally, or alternatively, the first region and the second region may be portions different from each other in a three-dimensional structure of the instrument. In this way, it is easy to distinguish each region in an electron microscope image.

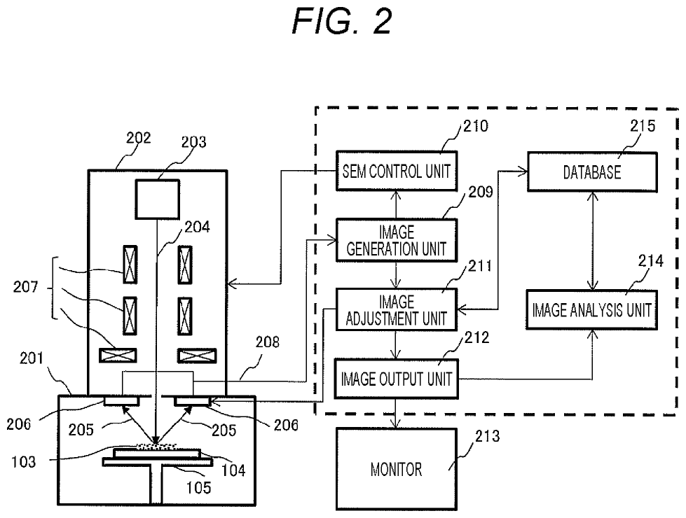

A schematic configuration of the particle analyzing device will be described with reference to FIG. 2. In FIG. 2, 103 denotes particles to be analyzed, 104 denotes an instrument, 105 denotes a sample stage, 201 denotes an SEM sample chamber, 202 denotes a lens barrel, 203 denotes an electron gun that irradiates the instrument and the particles with an electron beam, 204 denotes an electron beam, 205 denotes a backscattered electron and a secondary electron, 206 denotes a detector that detects an electron generated by irradiation of the electron beam, 207 denotes an electron optical system, 208 denotes a detection signal, 209 denotes an image generation unit, 210 denotes an SEM control unit, 211 denotes an image adjustment unit, 212 denotes an image output unit, 213 denotes a monitor, 214 denotes an image analysis unit, and 215 denotes a database. As will be described later, the monitor 213 functions as an image output unit that outputs an electron n microscope image whose brightness has been adjusted. With such a configuration, the particle analyzing device can generate an electron microscope image.

The particles to be analyzed 103, the instrument 104, and the SEM sample stage 105 are installed in the SEM sample chamber 201. In the SEM lens barrel 202, there are the detector 206 that detects a signal 205 of backscattered electrons and secondary electrons generated by irradiating the particles with the electron beam 204 emitted from the electron gun 203, and the electron optical system 207 that controls the electron beam 204. Moreover, an image of the particles placed on the instrument is generated by the image generation unit 209 that converts the signal 208 into image data. The SEM control unit 210 adjusts the focus of the SEM by using a boundary line image of the regions having different brightness in the instrument and the instrument background of the generated image.

Setting information of the particle analyzing device, such as a type of the instrument, image brightness of the instrument, and image adjustment and image analysis parameters described below, can also be accumulated in the database 215. Moreover, the settings of the image adjustment unit 211 and the image analysis unit 214 may be updated by analyzing the information accumulated in the database.

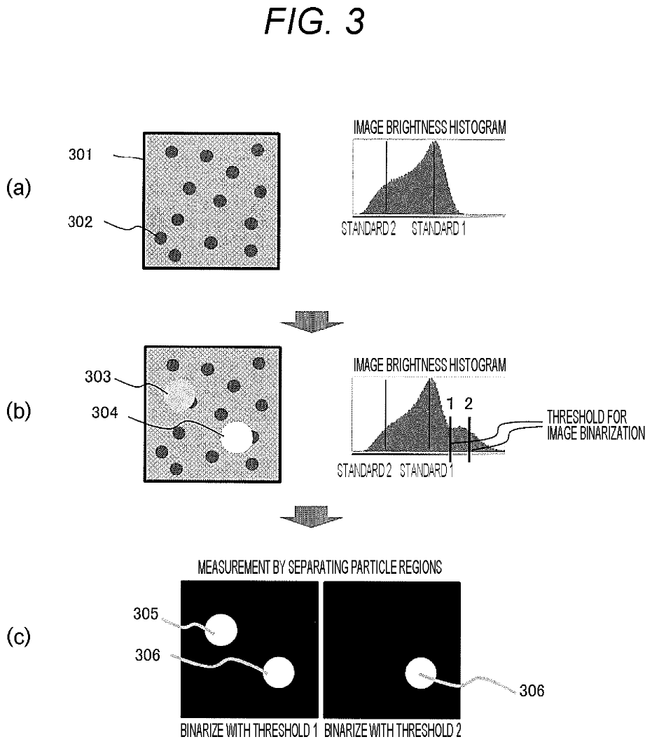

Adjustment of brightness and contrast in the image adjustment unit 211 will be described with reference to FIG. 3. In FIG. 3, 301 denotes an image of a background of an instrument, 302 denotes an image of a region where brightness of the instrument is different, 303 denotes an image of particles to be analyzed, 304 denotes an image of particles whose state has changed, and 305 and 306 denote particle images separated from the instrument image by binarization of the image.

The particle analyzing device stores a first standard value and a second standard value regarding brightness in an electron microscope image (simply referred to as “standard 1” and “standard 2” in the drawing). These standard values can be determined and input in advance by a user of the particle analyzing device. Hereinafter, specific examples of methods of determining these standard values will be described.

For example, the first standard value can be determined based on the brightness of the first region of the instrument, and the second standard value can be determined based on the brightness of the second region of the instrument. In the instrument on which the particles are placed, there are a background 301 and a region 302 having brightness different from that of the background 301 in the instrument image. By setting the brightness of the background 301 to the first standard value and setting the brightness of the region 302 having different brightness to the second standard value, and setting the first standard value and the second standard value to different appropriate positions in a brightness histogram of the entire image, it is possible to appropriately adjust the brightness and contrast of the generated image. Note that a specific method of adjusting the brightness and contrast of the image will be described in detail in Examples 2 and 3.

When the images of the particles 303 and 304 to be analyzed are generated, as illustrated in FIG. 3 (a), in the image adjustment unit, the adjustment of the brightness and the contrast is set to be constant using the first standard value and the second standard value, whereby the image brightness of the instrument region can be made constant in the plurality of generated images.

As illustrated in FIG. 3(b), it is possible to determine a threshold for binarizing the brightness of the image by using the fact that the brightness of the background 301 of the instrument, the region 302 having a different brightness from the background, and the particles 303 and 304 to be analyzed is different. The image analysis unit performs particle analysis by binarizing the brightness of the generated image to separate the particle image region and the instrument image region.

At this time, as described above, since the image brightness of the instrument region is constant even in a plurality of images, it is possible to separate the particle image and the instrument image as illustrated in FIG. 3 (c) by performing binarization with a certain brightness threshold. Moreover, even in a case where the particles 304 whose state has changed appear, the first standard value, the second standard value, and the image brightness of the particles 303 are constant. Therefore, the regions of 305 and 306 can be separated by binarizing the image with a threshold 1, and the particles 306 can be separated by binarizing the image with a threshold 2. After the particles are separated in this manner, the size, area, number, density, and the like of the particles can be analyzed.

Here, it is also possible to store a certain threshold optimized in advance as the threshold at the time of binarizing the image by the image analysis unit, and it is also possible to automatically calculate an appropriate threshold from the brightness histogram of the images of the particles to be analyzed and the instrument.

The image generated after the adjustment of the brightness and the contrast is displayed on the monitor via the image output unit. Parameters such as a threshold used when the image analysis unit separates the particle image and the instrument image can be accumulated in the database, and further fed back to the image adjustment unit, so that the parameters can be used for setting of image adjustment.

As described above, according to the particle analyzing device according to Example 1, it is easier to adjust the brightness of the electron microscope image.

Furthermore, although the example in which the database and the image analysis unit are integrated inside the particle analyzing device has been described, the database and the image analysis unit may be connected as attached devices.

### Example 2

Hereinafter, Example 2 of the present invention will be described. Descriptions of parts common to Example 1 may be omitted.

### <Track Etched Membrane>

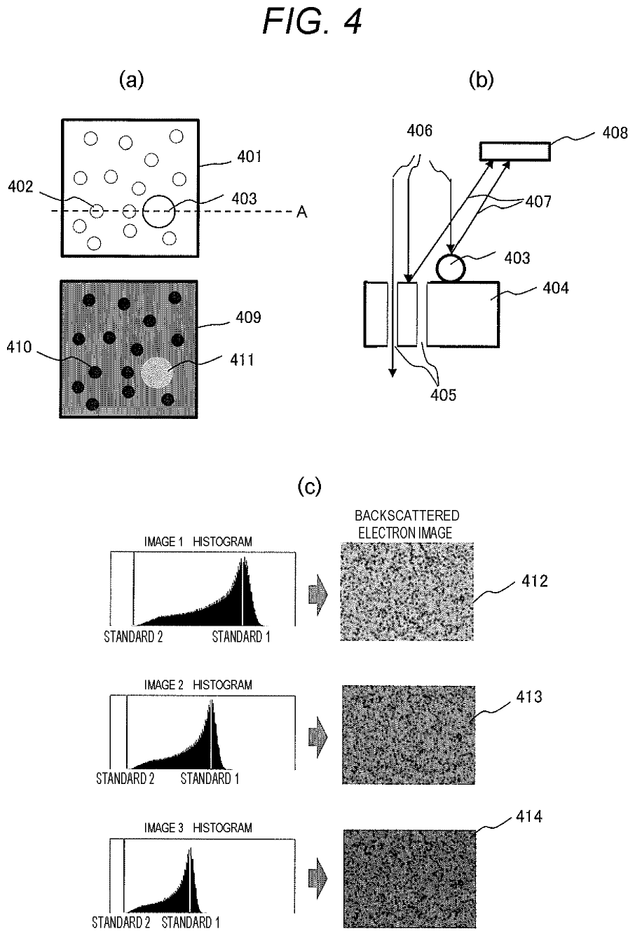

An example in which the instrument on which the particles are placed includes an instrument background and a region having different brightness will be described with reference to FIG. 4. In FIGS. 4 (a) and 4 (b), 401 is a top view of a track etched membrane, 402 is a through hole of the track etched membrane, 403 is a particle to be analyzed, 404 is a schematic cross-sectional view of the membrane at a line A in FIG. 4 (a), 405 is a cross section of a hole penetrating the membrane, 406 is an electron beam, 407 is backscattered electrons, 408 is a backscattered electron detector, 409 is an image of the track etched membrane, 410 is an image of the through hole of the track etched membrane, and 411 is an image of the particle to be analyzed.

For example, the instrument is a membrane 401 or 404 having the through hole 402 or 405 passing through the instrument. When a diameter of the through hole 402 or 405 is smaller than a minor diameter of the particle, it is preferable that the particle does not leak from the through hole 402 or 405. Furthermore, for example, when a liquid or gas in which particles are dispersed is placed on an instrument, the particles can be collected on one surface of the instrument, and impurities smaller than other solvents and particles can be discharged from the hole and separated, which is preferable.

Note that a diameter of the through hole 402 or 405 is, for example, a diameter when the cross section of the through hole is circular. Furthermore, the “minor diameter of the particle” is a diameter when the particle is spherical, a length of the shortest axis when the particle is ellipsoidal, and a diameter in a direction in which the diameter of the particle is minimum in a case where a size of the particle is not constant.

When the electron beam 406 is emitted, the backscattered electrons 407 generated in the instrument and the particles are detected by the detector 408, and the membrane image 409 and the particle image 411 are generated. On the other hand, since the electron beam passes through a portion of the through hole 405, the backscattered electrons do not reach the detector 408, and the image 410 of the through hole is a darkest portion in the generated image.

FIG. 4 (c) illustrates an example of a case where a polycarbonate track etched membrane having a hole diameter of 200 nm is observed at a magnification of 7000 times using a scanning electron microscope (SEM) as an example of such an instrument. In FIGS. 4 (c), 412, 413, and 414 denote backscattered electron images using the polycarbonate track etched membrane.

A histogram of brightness in each image is illustrated on the left of the respectively corresponding image. In the histogram, a horizontal axis represents a brightness value of a pixel, and a vertical axis represents a frequency (the number of pixels having that brightness value in the image).

The backscattered electron images 412, 413, and 414 are examples of images obtained by converting brightness from one image obtained by capturing the same field of view. The backscattered electron image 412 is obtained by applying a first conversion formula to the brightness of each pixel of the original image, the backscattered electron image 413 is obtained by applying a second conversion formula to the brightness of each pixel of the original image, and the backscattered electron image 414 is obtained by applying a third conversion formula to the brightness of each pixel of the original image.

For example, the brightness indicating a frequency peak in the histogram of the image brightness of the polycarbonate membrane is set as the first standard value, and the brightness of the darkest portion of the through hole is set as the second standard value. The first conversion formula applied to the backscattered electron image 412 converts the first standard value into a first target value and converts the second standard value into a second target value. By applying this first conversion formula to the brightness of all the pixels, the brightness of all the pixels is converted, and as a result, the backscattered electron image 412 is generated.

Similarly, the second conversion formula applied to the backscattered electron image 413 converts the first standard value into a third target value (which is smaller than the first target value), and converts the second standard value into a fourth target value (which is smaller than the second target value).

The third conversion formula applied to the backscattered electron image 414 converts the first standard value into a fifth target value (which is smaller than the third target value), and converts the second standard value into a sixth target value (which is smaller than the fourth target value).

The conversion formula can be automatically determined based on the target value. For example, the particle analyzing device can acquire the first target value and the second target value by outputting the signal profile and prompting an input corresponding thereto. Note that, in the present example, the “signal profile” includes information for each brightness value representing the number of pixels having the brightness value, and is represented, for example, in the form of a histogram illustrated in FIG. 4 (c). The monitor 213 may display the signal profile.

The first standard value and the second standard value may be indicated in the histogram. Here, the user of the particle analyzing device can determine and input the appropriate first target value and second target value by looking at the histogram. Then, the particle analyzing device determines a conversion formula for converting the first standard value into the first target value and converting the second standard value into the second target value in the signal profile. Such a conversion formula can be determined by a known method. For example, in a case where all of the first standard value, the first target value, the second standard value, and the second target value are scalar quantities, linear transformation may be used. Then, the particle analyzing device adjusts the brightness of the electron microscope image by applying the conversion formula to the brightness of the electron microscope image (brightness value of each pixel), thereby generating the backscattered electron images 412, 413, and 414.

In this way, three images with different brightness and contrast are generated. In this manner, the brightness and contrast of the image can be arbitrarily adjusted by changing the target values after conversion of the first standard value and the second standard value.

Moreover, not only at the time of image generation but also after output, when the images are images of particles placed on the same instrument, the brightness and contrast of the images can be adjusted by the image analysis unit using the brightness first standard value and the brightness second standard value of the instrument.

For example, image analysis software or the like is used to display a histogram of the brightness of the plurality of output images, and the first standard value and the second standard value are converted into constant target values to adjust the brightness and contrast of the image. Here, by setting the first standard value and the second standard value to be large for an instrument that becomes a bright image as a whole, and setting the first standard value and the second standard value to be small for an instrument that becomes a dark image as a whole, it is possible to equalize the brightness of the entire image by inputting the same target value for the instrument having different brightness. Thereafter, by binarizing the plurality of images with the same threshold, the particle image and the instrument image can be appropriately separated in all the images.

### Example 3

Hereinafter, Example 3 of the present invention will be described. Descriptions of parts common to Example 1 or 2 may be omitted.

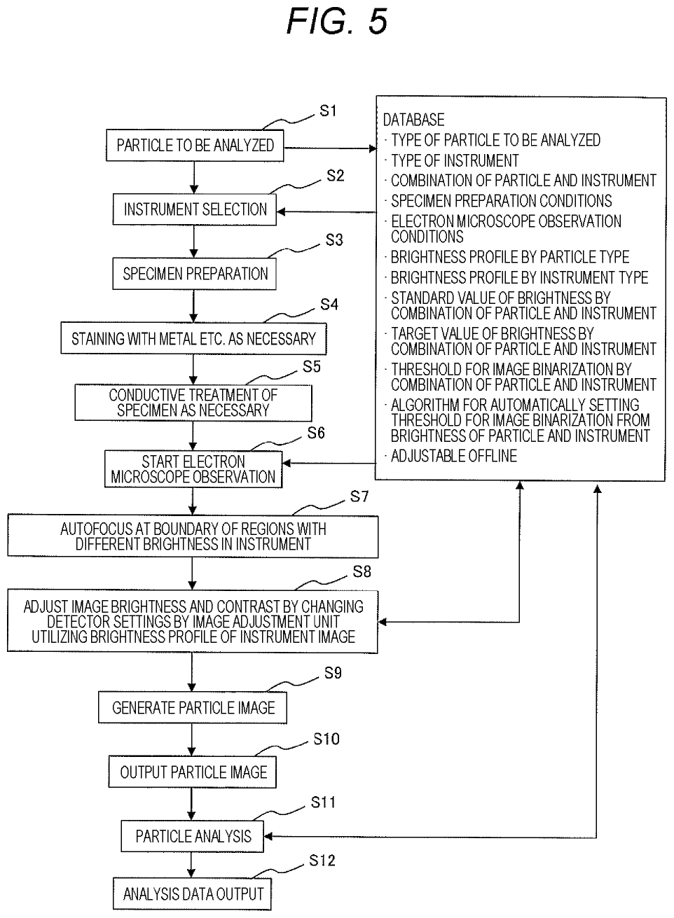

An example of a flow of a particle analyzing method is illustrated in FIG. 5. The user of the particle analyzing device determines a type of the particle to be analyzed (S1), and further determines a type of the instrument (S2). In response to this, the particle analyzing device acquires the type of the particle and the type of the instrument. Here, the type may indicate, for example, the properties of the particle or the instrument.

Then, the particle analyzing device refers to the database and acquires various information. The obtained information includes, but is not limited to, the following by way of example:
Example of signal profile of brightness associated with particle type;
Example of signal profile of brightness associated with instrument type;
Specimen preparation conditions associated with combination of particle type and instrument type;
Electron microscope observation conditions associated with combination of particle type and instrument type;
First standard value and second standard value associated with combination of particle type and instrument type;
First target value and second target value associated with combination of particle type and instrument type; and
Threshold for binarization associated with combination of particle type and instrument type.

In particular, the particle analyzing device acquires the first standard value and the second standard value based on the type of the particle and the type of the instrument. As a result, same standard values can always be acquired for a same type combination of particle and instrument.

Here, the user preferably selects an instrument exhibiting image brightness different from that of the particle. Furthermore, in a case where the type of the particle to be analyzed does not exist in the database, it is preferable to select an instrument constituted by an element different from an element constituting the particle to be analyzed. Alternatively, in a case where the particle is a stained particle, it is preferable to select an instrument exhibiting image brightness different from that of the particle. Alternatively, it is preferable to select an instrument exhibiting image brightness different from that of the particle due to a three-dimensional structure or the like.

Note that, in a modification, the particle analyzing device may have a function of automatically setting a threshold for image binarization from brightness of the particle and the instrument, and may acquire an algorithm for realizing such a function from the database.

Next, the user prepares a specimen on which the particle is placed on the instrument (S3), stains the particles with a stain containing metal or the like according to specimen preparation conditions, and uses the stained particle (S4). The staining makes it easier to distinguish from the instrument. Furthermore, in a case where the particle or the instrument is a non-conductive substance, a conductive treatment is performed by metal coating or the like as necessary (S5). Note that the staining and the conductive treatment may be performed before the particle is placed on the instrument.

Next, the user places the instrument on which the particle is placed on the sample stage of the electron microscope, inserts the instrument into the electron microscope sample chamber, and starts the observation (S6). In a case where observation conditions such as an acceleration voltage, a current value, an observation magnification, and a degree of vacuum of the electron microscope are registered in the database according to a combination of the particle and the instrument, the particle analyzing device may control the SEM using the observation conditions. In the image displayed on the monitor, the particle analyzing device uses a boundary of regions having different brightness in the instrument to focus the image (S7). Such a focusing method can be appropriately designed based on a known technique.

Here, the particle analyzing device acquires an electron microscope image and a signal profile generated by irradiating the instrument and the particle with an electron beam.

Subsequently, the particle analyzing device adjusts the image brightness and contrast (S8). This adjustment can be realized, for example, by changing the setting of the detector of the electron microscope. For example, as described in Example 2, the particle analyzing device adjusts the brightness of the electron microscope image using, for example, the conversion formula based on the first standard value, the second standard value, and the signal profile. Furthermore, the contrast is adjusted by adjusting the brightness.

Next, the particle analyzing device may focus on the particle to be analyzed based on the electron microscope image after the brightness is adjusted. Next, the particle analyzing device generates a particle image to be used for particle analysis (S9). The brightness of the particle image can also be adjusted by applying the brightness conversion formula used in S8. Furthermore, the particle analyzing device generates, outputs, and stores an image in which an observation position magnification are changed according to the operation of the user (S10). In the case of the scanning electron microscope, since the adjustment of the brightness and contrast of the image does not change even if the magnification is changed, a plurality of images having different magnifications can also generate and output images under the same condition.

Subsequently, the output image is analyzed (S11). For example, the threshold for image binarization may be automatically set from the brightness of the particle and the instrument according to the purpose of identifying the regions of the particle and the instrument, further identifying the type of the particle, or the like. Alternatively, regarding the threshold, a value registered in the database may be referred to.

In the case of a plurality of images generated by the same brightness and contrast adjustment (for example, the same conversion formula), a binarized image can be quickly generated by using a macro function of the image analysis software, and the size, area, and the like of particles can be analyzed.

The conditions selected or set in each step of FIG. 5 and the output analysis and evaluation results are output and registered in the database (S12). The particle analyzing device may obtain an optimum condition of the particle analysis flow by analyzing the registered data, and feed back the optimum condition to the setting of the particle analyzing device.

The flow illustrated in FIG. 5 is an example of the particle analyzing method according to the present example, and the flow of the present example is not limited to FIG. 5.

For example, in the present example, the particle analyzing device adjusts the brightness of the electron microscope image online, but as a modification, the brightness of the electron microscope image may be adjusted offline. That is, the SEM may be first controlled to acquire and store an electron microscope image, and then the control of the SEM may be terminated (for example, in a state where the operation of the electron gun 203 and the detector 206 of the SEM is stopped, or in a state where the power supply of the SEM is turned off) to acquire a stored electron microscope image and adjust the brightness thereof. In this way, the convenience of the user is improved.

### Example 4

Hereinafter, Example 4 of the present invention will be described. Descriptions of parts common to any of Examples 1 to 3 may be omitted.

### <Analysis of Blood Cells>

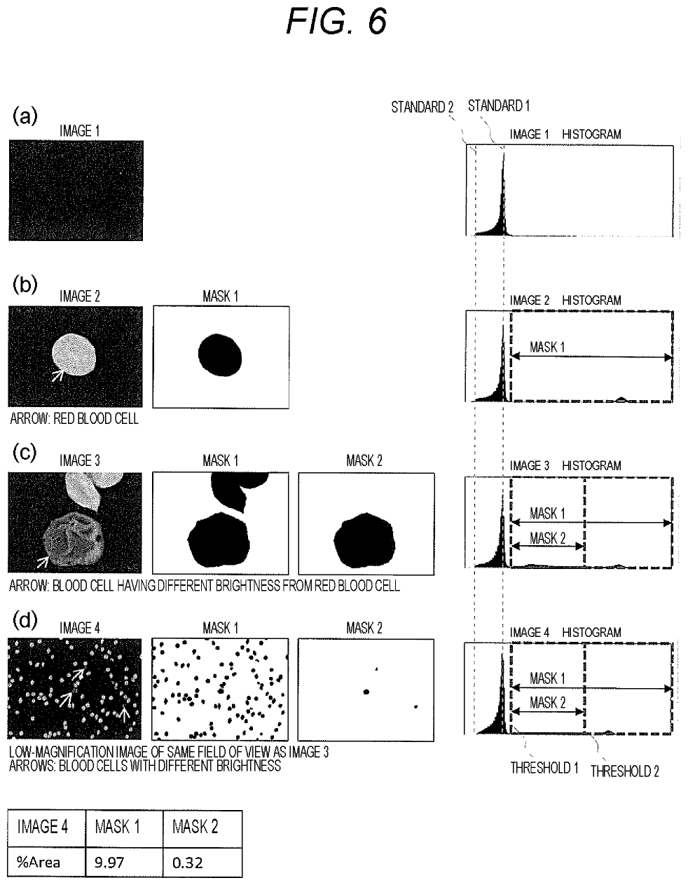

An example of analyzing blood cells using the present example will be described with reference to FIG. 6. Human blood was diluted with saline and placed on a track etched membrane filter with a 200 nm diameter through hole. On a surface of the membrane, platinum palladium was previously deposited to impart conductivity to the specimen.

The blood cells on the membrane were fixed with a fixing solution having a protein crosslinking action such as glutaraldehyde, then the blood cells were stained using a staining solution containing a metal, the excess staining solution was washed away with water, and then dried, and then the blood cells were inserted into a scanning electron microscope sample chamber, and a backscattered electron image was observed at magnification of 5000 times.

An image 1 of FIG. 6 (a) is a membrane image, and after focusing on an outline of the through hole, in the brightness histogram, the brightness of a frequency peak corresponding to the brightness of a membrane material was set as a first standard value, and the brightness corresponding to a darkest portion which is the through hole was set as a second standard value, and the values of the horizontal axes of the first standard value and the second standard value were set, thereby adjusting the brightness and contrast of the image.

An image 2 in FIG. 6 (b) is an image of one red blood cell. An image 3 of FIG. 6 (c) is an image of a red blood cell and another blood cell having different brightness from the red blood cell. In FIG. 6 (d), an image 4 is an image having the same region at a center as that of the image 3 and having a magnification of 500 times. In the histograms illustrated on the right side of the images of FIGS. 6 (a) to 6 (d), the first standard values and the second standard values are respectively the same values.

Using the image analysis software, masks of the images 2, 3, and 4 were created. The mask 1 is a mask image created by binarizing with a first threshold (threshold 1) of the brightness histogram of each image and then removing particles significantly smaller than blood cells by a particle analysis algorithm. The mask 2 is a mask image created by binarizing the image with a threshold 2 of the histogram and then removing particles significantly smaller than blood cells by a particle analysis algorithm.

As a result of obtaining an area by the particle analysis, since an area ratio (% Area) of the mask 1 in the image 4 was 9.97% and an area ratio of the mask 2 was 0.32%, it was shown that about 3% of the blood cells were blood cells having different brightness.

### Example 5

Hereinafter, Example 5 of the present invention will be described. Descriptions of parts common to any of Examples 1 to 4 may be omitted.

### <Analysis of Cell Proliferation>

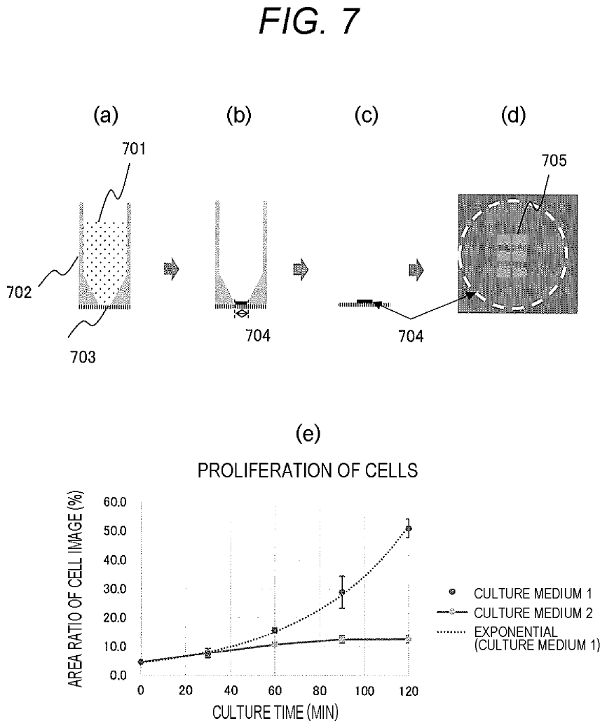

An example in which a proliferation rate of cells is obtained using this example will be described with reference to FIG. 7. In FIG. 7, 701 denotes a cell culture solution, 702 denotes a funnel, 703 denotes a track etched membrane filter, 704 denotes a cell collection region, and 705 denotes an image generation region.

A fixed amount of the cell culture solution 701 was sampled from a cell culture vessel at regular time intervals, and was collected in a certain region on the membrane filter using a cell collection device. On a surface of the membrane, platinum palladium was deposited in advance to impart conductivity to the specimen.

As illustrated in FIG. 7 (a), the cell collecting device has a structure in which a track etched membrane filter 703 having a through hole having a diameter of 200 nm, which is smaller than a minor diameter of the cell, is installed on a bottom surface of the funnel-shaped container 702. The sampled cell culture solution 701 was injected into the funnel part, the solution was discharged by sucking the solution from an opposite side of the membrane filter, and the cells were collected on the upper surface 704 of the membrane filter as illustrated in FIG. 7 (b).

The cells were fixed with a fixing solution having a protein crosslinking action such as 2.5% glutaraldehyde so that the cells were not changed, and then the cells were stained using a staining solution containing a metal. As illustrated in FIG. 7 (c), after the excess stain solution was washed away with water, the membrane filter was taken out from the cell collection device and dried, and then a backscattered electron image was observed by SEM.

As a step of observation, first, the magnification was set to 7000 times in a region where no cell was placed in the specimen, and the image was focused on an outline of the hole of the track etched membrane using an autofocus function of the SEM. Next, the brightness and contrast of the image were adjusted according to Example 2. In the images of all specimens sampled over time, the brightness indicating a frequency peak of the brightness of the polycarbonate membrane in the brightness histogram was set as a first standard value, and the brightness indicating a frequency peak of the brightness of the hole portion was set as a second standard value, and the same conversion formula was applied to adjust the brightness and contrast. The values of the first standard value and the second standard value were determined to be appropriate values for separating the cell image and the instrument image by binarization at the stage of preliminary examination.

The reason for the magnification of 7000 times is selected as a magnification at which the outline of the track etched membrane can be clearly imaged at the time of focusing, but is not limited thereto.

Subsequently, the magnification was changed to 500 times, and as illustrated in FIG. 7 (d), 6 images 705 were acquired at equal intervals in the region where the cells on the membrane were collected. At this time, a plurality of images can be easily generated by using the electric sample stage built in the SEM and an automatic continuous image-capturing function.

The reason why the imaging magnification is set to 500 times is that it is desirable to set the magnification to be low in order to image a wide region with a small number of images and to be able to distinguish the shape of the cell from noise, and thus 500 times in which one pixel is sufficiently smaller than a diameter of the cell is selected, but the imaging magnification is not limited to this magnification. The number of images is, for example, six in order to average the density bias in the region where the cells are collected, but is not limited to this number.

The output image was input offline to the image analysis unit, all the images were binarized at a constant threshold using the image analysis software, and then an image area ratio of the particle portion was obtained. By using the macro function provided to the image analysis software, it is possible to perform a step of binarizing with a certain threshold optimized in advance and a step of obtaining the area of the particle portion in a few seconds.

A step of sampling cells cultured in two types of media 5 times over time and acquiring 30 images (6 images per specimen) was independently repeated 3 times to generate 180 images.

The results of analyzing the proliferation of cells using the method of this example are illustrated in a graph of FIG. 7 (e). When cultured in a medium 1, the cells proliferated exponentially. A dotted line in the graph represents an exponential function that approximates an area ratio of the culture medium 1. On the other hand, when the cells were cultured in a medium 2 (solid line), proliferation was suppressed. As described above, by using the method of this example, it is possible to easily analyze the proliferation of the cultured cells.

### Example 6

Hereinafter, Example 6 of the present invention will be described. Descriptions of parts common to any of Examples 1 to 5 may be omitted.

### <Analysis of Asbestos>

At a building dismantling site where a building material contains asbestos fibers, atmospheric concentration measurement may be performed in order to monitor leakage of asbestos. The air in the working environment is sucked into the filter for a certain period of time, and the asbestos fiber concentration is measured on a surface of the filter using an optical microscope or an electron microscope. On the other hand, mesothelioma is an example of health damage caused by asbestos, and there is a case where asbestos fibers contained in a solution of a patient specimen are recovered to a nitrocellulose membrane filter or the like and quantified in order to provide a basis for patient relief. In such an analysis of asbestos, the device and the method of the present example can be applied.

For example, since the components of the nitrocellulose membrane are composed of elements lighter than silicon, magnesium, iron, and the like contained in asbestos, the backscattered electron image acquired by SEM is an image darker than asbestos. By providing one or more types of regions having different brightness on the nitrocellulose membrane, brightness and contrast at the time of image acquisition are adjusted using brightness indicating a frequency peak of brightness of nitrocellulose as a first standard value and brightness indicating a frequency peak of brightness of a region having different brightness as a second standard value.

When images of different specimens are acquired, the brightness and contrast of the images are adjusted using a nitrocellulose membrane provided with regions having different brightness. By binarizing the plurality of images generated in this manner with an appropriate threshold in the image analysis unit, it is possible to separate images of the instrument and bright fibers on the instrument.

An actual specimen often contains many fibrous foreign matters other than asbestos. Furthermore, image brightness varies depending on the type of asbestos due to a difference in constituent elements and fiber thickness. In order to classify them, the image analyzing device binarizes the images in stages using a plurality of thresholds, so that the fiber image can be classified by the brightness of the backscattered electron image.

A fiber image in a brightness range including asbestos is extracted by collating with previously accumulated data on brightness of a backscattered electron image of asbestos. By performing elemental analysis using SEM on the fibers extracted in this way, asbestos can be identified and quantified.

### REFERENCE SIGNS LIST

101 particle
102 top view of instrument
103 side view of particle
104 side view of instrument
105 sample stage
103 particle
104 instrument
105 sample stage
201 SEM sample chamber
202 lens barrel
203 electron gun
204 electron beam
205 backscattered electron and secondary electron
206 detector
207 electron optical system
208 detection signal
209 image generation unit
210 SEM control unit
211 image adjustment unit
212 image output unit
213 monitor (image output unit)
214 image analysis unit
215 database
301 image of instrument background
302 image of region with different brightness of instrument
303 particle image
304 image of particle whose state has changed
305, 306 particle image separated from instrument image by binarization of image
401 top view of track etched membrane
402 through hole of track etched membrane
403 particle
404 schematic cross-sectional view of membrane
405 cross-section of hole through membrane
406 electron beam
407 backscattered electron signal
408 backscattered electron detector
409 image of track etched membrane
410 image of through hole of track etched membrane
411 image of particle to be analyzed
412, 413, 414 backscattered electron image
701 cell culture solution
702 funnel
703 track etched membrane filter
704 cell collection region
705 image generation region

1. A particle analyzing device for analyzing a predetermined particle to be analyzed, placed on an instrument, with an electron microscope, wherein
the particle analyzing device acquires a first standard value and a second standard value regarding brightness in an electron microscope image,
the particle analyzing device acquires an electron microscope image and a signal profile generated by irradiating the instrument and the particle with an electron beam,
the particle analyzing device adjusts brightness of the electron microscope image based on the first standard value, the second standard value, and the signal profile,
the instrument includes a first region having different brightness from the particle and a second region having different brightness from the particle and the first region when observed with the electron microscope,
the first standard value is a value determined based on brightness of the first region, and
the second standard value is a value determined based on brightness of the second region.

2. The particle analyzing device according to claim 1, wherein
the particle analyzing device acquires a type of a particle and a type of an instrument, and acquires the first standard value and the second standard value based on the type of the particle and the type of the instrument.

3. (canceled)

4. The particle analyzing device according to claim 1, wherein
a material constituting the first region is different from a material constituting the second region.

5. The particle analyzing device according to claim 1, wherein
the first region and the second region are portions different from each other in a three-dimensional structure of the instrument.

6. The particle analyzing device according to claim 1, wherein
the particle is a stained particle.

7. The particle analyzing device according to claim 1, further comprising:
an electron gun that irradiates the instrument and the particle with an electron beam;
a detector that detects electrons generated by irradiation with the electron beam; and
an image output unit that outputs an electron microscope image whose brightness has been adjusted.

8. The particle analyzing device according to claim 7, wherein
brightness of the electron microscope image is adjusted offline.

9. The particle analyzing device according to claim 1, wherein
the instrument includes a through hole penetrating the instrument, and a diameter of the through hole is smaller than a minor diameter of the particle.

10. The particle analyzing device according to claim 1, wherein
the particle analyzing device outputs the signal profile,
the particle analyzing device acquires a first target value and a second target value,
the particle analyzing device determines a conversion formula for converting the first standard value into the first target value and converting the second standard value into the second target value in the signal profile, and
the particle analyzing device adjusts brightness of the electron microscope image by applying the conversion formula to the brightness of the electron microscope image.

11. A particle analyzing method for analyzing a predetermined particle to be analyzed, placed on an instrument, with an electron microscope, the particle analyzing method comprising:
acquiring a first standard value and a second standard value regarding brightness in an electron microscope image;
acquiring an electron microscope image and a signal profile generated by irradiating the instrument and the particle with an electron beam; and
adjusting brightness of the electron microscope image based on the first standard value, the second standard value, and the signal profile,
wherein
the instrument includes a first region having different brightness from the particle and a second region having different brightness from the particle and the first region when observed with the electron microscope,
the first standard value is a value determined based on brightness of the first region, and
the second standard value is a value determined based on brightness of the second region.
